(19) United States
(12) Patent Application Publication
(10) Pub. No.: US 2002/0036506 A1
(43) Pub. Date: Mar. 28, 2002

(54) Device to facilitate loading of an emulsion loop

(76) Inventor: Bentley N. Scott, Garland, TX (US)

Correspondence Address: Groover & Associates p.c., Suite 230, 17000 Preston Road, Dallas, TX, 75248, US

(21) Appl. No.: 09/891,098

(22) Filed: Jun. 25, 2001

Related U.S. Application Data
(60) Provisional application No. 60/213,921, filed on Jun. 26, 2000.

(51) Int. Cl. G01R 27/04; G01R 27/32

(52) U.S. Cl. 324/637

(57) ABSTRACT

In a test loop for verification of the compositions of emulsions, precise amounts of the components must be added. A piston temporarily increases the volume of the loop to allow the addition of liquids without spilling or burping out the contents. After loading, the piston is raised to expel air in the loop, then a vacuum pump and very small tubing remove the last vestiges of trapped air. The piston may then be used in conjunction with the vacuum pump to pressurize the system to a desired pressure. Liquid flow is directly against the piston, which is ideally positioned to maintain a turbulence which keeps the components of the emulsion from separating. The piston also allows the addition of small amounts of one component after pressurizing to extend testing capabilities. A liquid injection pump injects a measured amount of a component, while the piston allows expansion of the loop volume within specified limits.

This application claims priority from U.S. Provisional Application 60/213,921, filed Jun. 26, 2000, which is hereby incorporated by reference.

### BACKGROUND AND SUMMARY OF THE INVENTION

The present invention relates to devices for the verification of compositions of emulsions, and especially to properly loading the testing device.

Background: Load-Pulled Oscillators

Extensive work by the present inventor and others has shown that load-pulled oscillators have important capabilities for measurement and characterization. See U.S. Pat. Nos. 4,862,060, 4,996,490, 5,025,222, 5,748,002, and 6,166,551, all of which are hereby incorporated by reference. This “load-pull” technology provides an economical measurement technique which has improved sensitivities by 100× to 1000× over any prior instrumentation for measurement of microwave phase.

These systems provide a generally applicable method for monitoring the characteristics of a substance. A probe is placed within the substance and coupled to an RF oscillator. Changes in the frequency of the oscillator provide a sensitive indicator of changes in the substance being monitored, such as water present in a stream of oil.

Background: Use of Emulsion Loop

In order to initially establish what a particular oscillator measurement means, tests are run with emulsions of known compositions, using an analyzer 15 with a verification loop 10, such as is seen in FIG. 6. These generally contain a pump 14 and motor 13 to move the emulsion and keep it mixed, a pressurization system to eliminate bubbles of air, an analyzer 15, a loading port 61, a static mixer and a heat exchanger (not shown) to heat or chill the emulsions.

In order for the analyzer to measure various percentages of say oil and water properly, the test loop must be loaded with a precisely known volume of each component. Additionally, the liquids must occupy the entire volume of the loop so that the operator can be assured that the percentage mixture is correct. The introduction of liquids into the system must be done carefully, so that no splashing or “burping” of the liquids causes them to be lost, while at the same time the fixed volume loop must be filled completely to prevent air bubbles.

Maintaining the proper composition is especially difficult when the two components separate easily, such as oil and water. Typically, one component tends to go to the bottom of the piping, so that if any liquid is lost when air is bled from the system, the percentages of the two components are changed. It has been desirable to add additional volume to the loop during loading, but this has not met with success in the past, as “dead” spaces can then be created in which portions of the emulsion are able to separate out.

Innovative Emulsion Loop Loading

The present application describes a movable piston device which can be raised and lowered to change the volume of the loop, but which does not cause the troublesome dead spaces of the past. By displacing the piston downward, the loop volume is increased, allowing the air and liquids to move past each other without losing any of the liquid to spills or eruptions of exiting air. After loading, the piston can be moved upwards to expel air in the lines out of the top of the piping. Then, after sealing of the loop, pressure on the backside of the piston will pressurize the entire loop. During operation of the analyzer, the output from the pump drives directly against the top of the piston, then exits slightly above and to the side of the piston. This creates turbulence in the flow, so that the heavier component will not have a chance to separate out.

In addition to the piston, a very small tubing (<1/16 inch) is placed at the highest point in the loop to remove the air which remains after the loop is closed. A jar is used to visually see when the liquids begin to come through the small tubing and keeps the liquids out of the vacuum pump. The same vacuum pump can be used to pressurized the system by switching the output to pressurize the piston.

A liquid injection pump combined with the piston can provide the ability to change the ratio of the components after sealing and pressurizing the system. Precise amounts of one component are injected into the loop under pressure, while the piston moves to take up the extra volume. This allows further calibration without unloading the loop.

The disclosed innovations, in various embodiments, provide one or more of at least the following advantages:

ease of loading liquids;

ease of eliminating air;

only minute amounts of liquid are lost when eliminating air bubbles;

no “dead” sections in loop;

emulsions remain mixed;

economical: piston both aids in loading and pressurizes system;

several calibrations can be done without opening the system.

### BRIEF DESCRIPTION OF THE DRAWING

The disclosed inventions will be described with reference to the accompanying drawings, which show important sample embodiments of the invention and which are incorporated in the specification hereof by reference, wherein:

FIG. 1 shows an overview of the system as the emulsion liquids are being loaded.

FIG. 2 shows an overview of the system after loading and pressurizing.

FIG. 3 shows the small tubing used to remove the last of the air remaining in the system.

FIG. 4 shows a detail of the piston during loading.

FIG. 5 shows a detail of the piston when the system is pressurized.

FIG. 6 shows an overview of the prior art system.

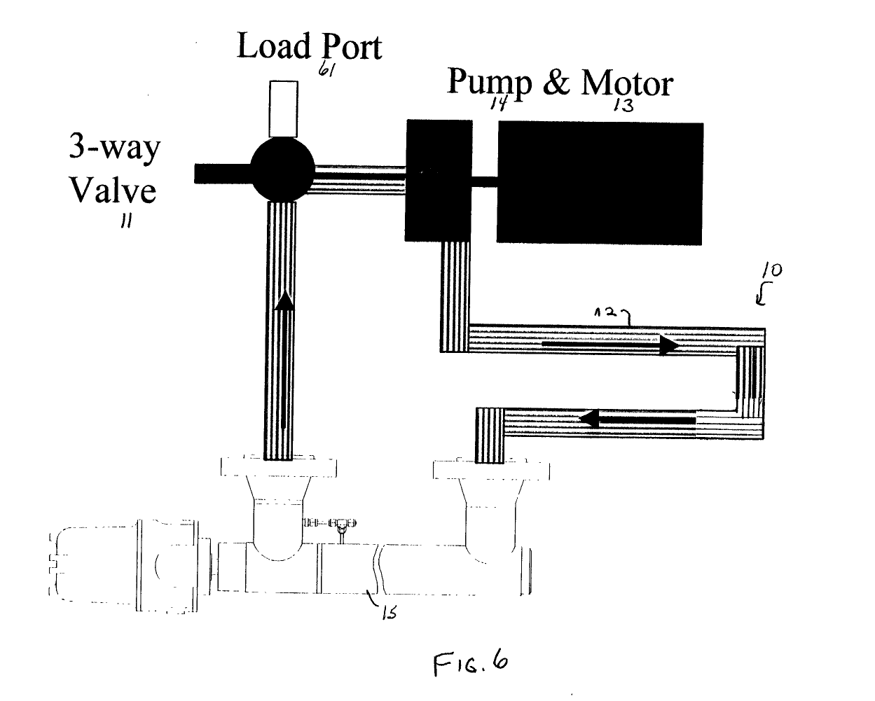

FIG. 7 shows the liquid injection pump which is used to add one component after pressurizing.

### DETAILED DESCRIPTION OF THE PREFERRED EMBODIMENTS

The accompanying drawings show important sample embodiments of the invention and are incorporated in the specification hereof by reference.

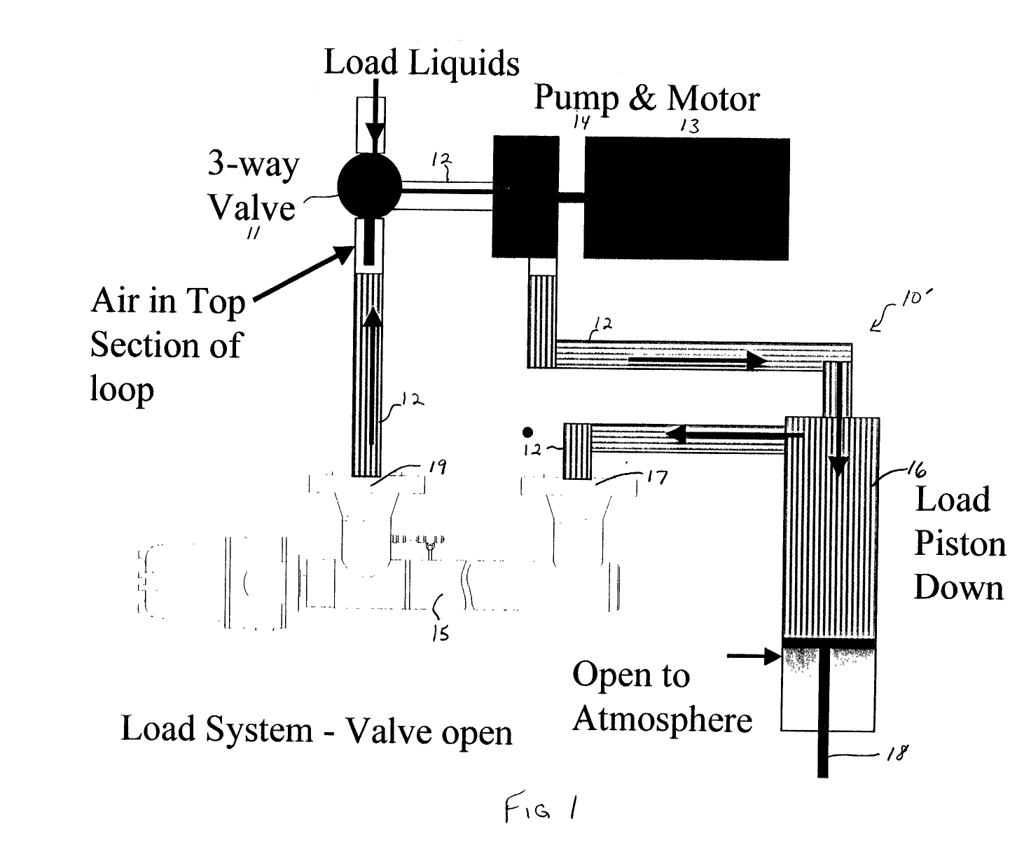

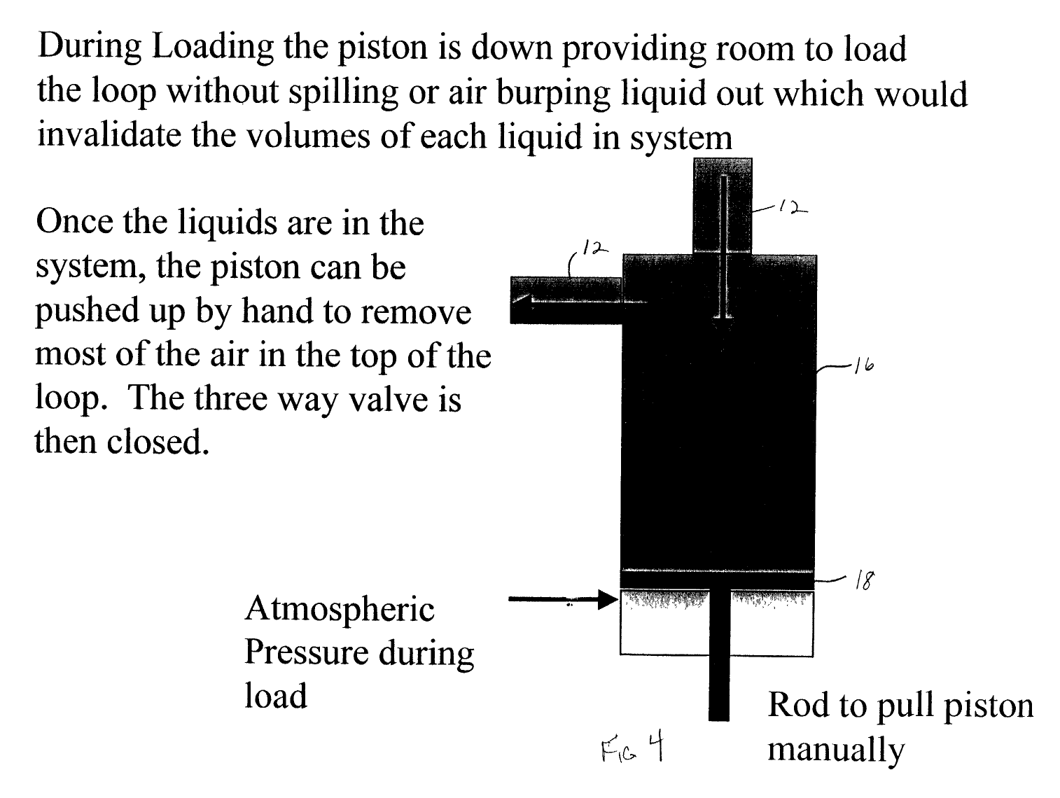

In an exemplary preferred embodiment, shown in FIG. 1, we see the system as the emulsion liquids are being loaded. It is worth noting at this point that the actual analyzer 15 is shown lighter than the other parts of the loop. This is because the details of this portion are not important to the invention and hence will not be discussed except to note its presence. Liquids enter the loop 10′ through a 3-way valve 11, which is positioned to also allow air to escape from the loop. Attached to the 3-way valve are sections of piping 12 which connect the valve to the pump 14 (powered by motor 13), the input port 17 and output port 19 of the analyzer 15, and to a larger section of piping 16 which contains the piston 18. During loading, the piston is down to provide room to load the loop without spilling any liquid or allowing the escaping air to burp liquid out. A detail of the piston at this point is shown in FIG. 4.

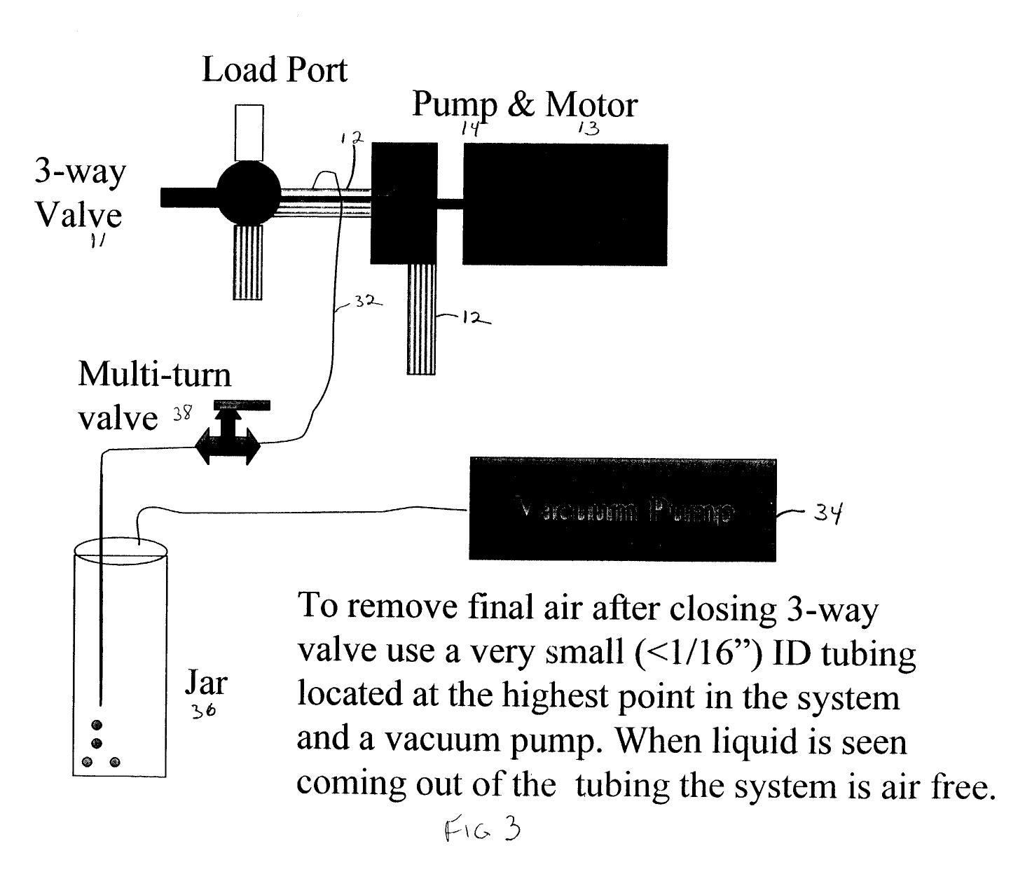

Once the carefully measured liquids are loaded into the system, the piston is raised, generally by hand, to remove most of the air which remains at the top of the loop and the valve is closed. In a preferred embodiment, the final air which remains after the valve is closed is removed by the vacuum system shown in FIG. 3. A very small diameter tube 32 is attached to the highest point in the loop, where air will naturally collect in the quiescent system. The inside diameter of this tubing is small enough to cause the liquids to create a large pressure drop across the tubing, generally less than 1/16 inch. The air is removed by a vacuum pump 34 attached to the tubing through a sealed jar 36. The jar 36 is used to visualize when liquids begin to come through the small tubing and keeps the liquids out of the vacuum pump. Once liquid starts to exit the loop, a valve 38 in the small tubing is sealed. The vacuum pump 34 is no longer needed to evacuate air and can be used to pressurize the system by switching the output to the backside of the piston 18.

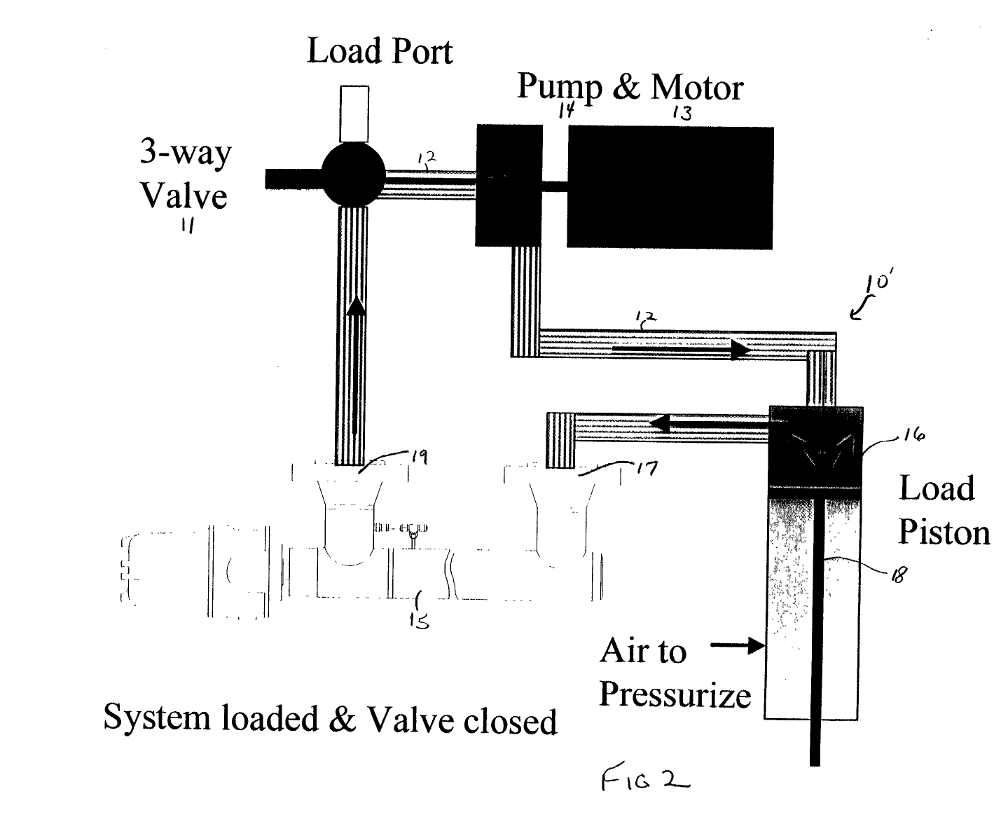

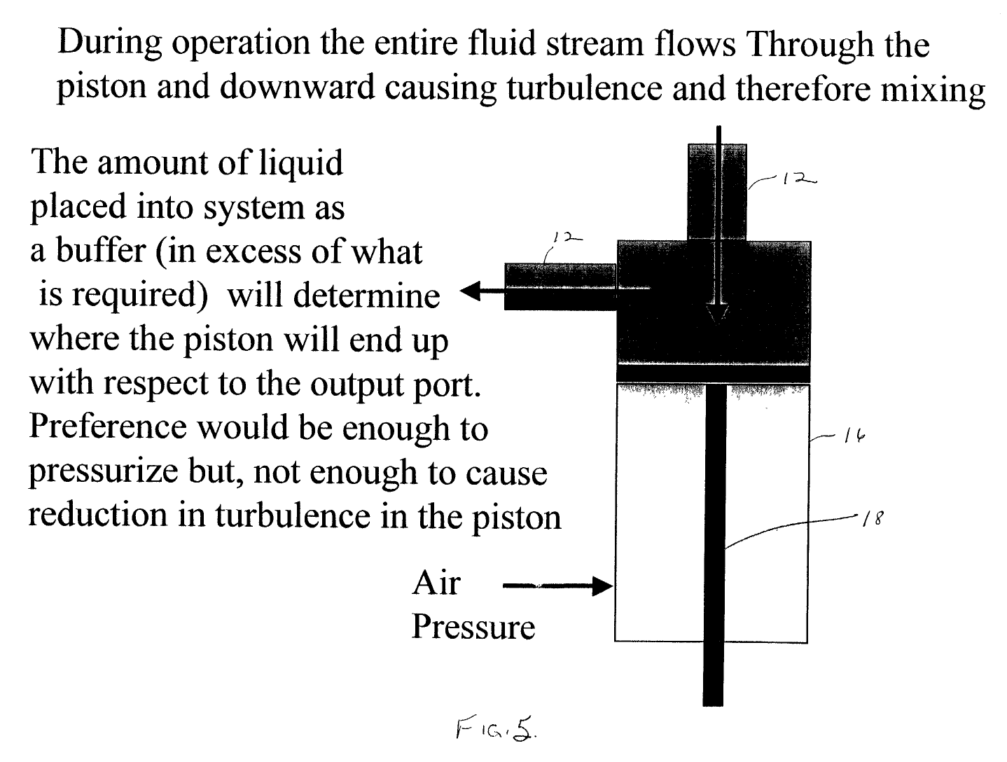

FIG. 2 shows an overview of the system after the system is loaded and the valve closed. Within the specified minimum and maximum amounts of liquid allowable in the system, the actual amount will determine where the piston ends up with respect to the output port. Because the flow of the liquid is directly against the piston, enough turbulence is created to keep the components of the emulsion from separating. See FIG. 5 for a detail of the piston after the system is sealed and pressurized.

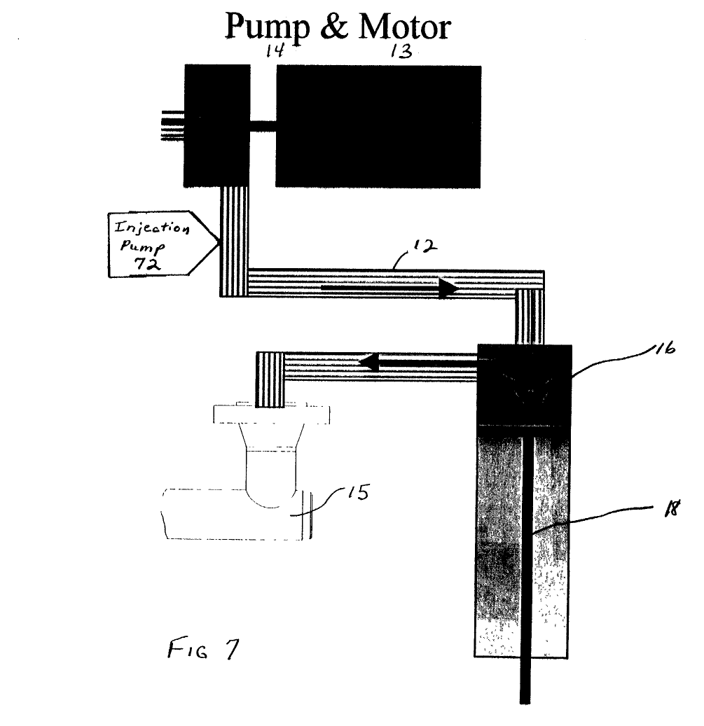

FIG. 7 shows a high pressure (greater than 500 pounds per square inch) liquid injection pump 72 which can be used to add one component to the emulsion after the system is closed. The pump 72 is a positive displacement type which assures a known amount is injected with each stroke, and which is typically used to inject chemicals into a process stream. Once the initial analysis of the emulsion has been done, this allows further calibration without unloading the loop. The piston 18 moves to accommodate the extra liquid volume; the pressure can be regulated easily by a control loop to either remain constant or increase. After the additional amounts are added, the main loop pump and the velocity of the flowing liquids in the main loop assure homogeneous mixing. Of course, only small amounts of additional fluid would be added, since extending the piston too far down would create an unwanted dead space.

Modifications and Variations

As will be recognized by those skilled in the art, the innovative concepts described in the present application can be modified and varied over a tremendous range of applications, and accordingly the scope of patented subject matter is not limited by any of the specific exemplary teachings given.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

What is claimed is:

1. A device for verifying the composition of an emulsion, said device comprising:
a loop of piping connected to the input valve of an analyzer and to the output valve of said analyzer;
a piston which is connected to said loop of piping in a manner to enable said piston to change the volume of liquid which can be contained in said loop of piping.

2. The device of claim 1, further comprising a pump to circulate a liquid which is contained in said loop of piping, said pump and said piston being positioned so that the flow of the liquid within said pump is substantially directed against said piston.

3. The device of claim 1, further comprising a vacuum pump which is connected to the highest point of said loop of piping through a section of tubing which is smaller than 1/16 inch in inside diameter.

4. The device of claim 1, further comprising a liquid injection pump which can inject small amounts of a component into the loop after sealing and pressurization of the loop have been performed.

5. A device for verifying the composition of an emulsion, said device comprising:
an analyzer;
a loop of piping connected to an input valve of said analyzer and to and output valve of said analyzer;
a valve which allows the introduction of liquids into said loop;
a pump connected to said loop of piping to maintain a flow of liquids through said loop;
a piston which is connected to said loop of piping in a manner to enable said piston to change the volume of liquid which can be contained in said loop of piping.

6. The device of claim 5, further comprising a vacuum pump which is connected to the highest point of said loop of piping through a section of tubing which is smaller than 1/16 inch in inside diameter.

7. The device of claim 5, further comprising a liquid injection pump which can inject small amounts of a component into the loop after sealing and pressurization of the loop have been performed.

8. A method of loading an emulsion loop, comprising the steps of:
lowering a piston which is a part of said loop in order to increase the volume of said loop;
while said piston is in a lowered position, adding liquids to said loop through an input valve;
after said liquids are added, raising said piston to expel a majority of air in said loop;
after said piston is raised, closing said input valve.

9. The method of claim 8, further comprising, after said input valve is closed, pressurizing said loop.

10. The method of claim 8, further comprising, after said input valve is closed, removing remaining air using a pressure pump and a section of tubing having an inside diameter of 1/16 inch.

11. The method of claim 8, further comprising, after said input valve is closed, adding a liquid to said emulsion using a liquid injection pump.
